(19) United States
(12) Patent Application Publication
(10) Pub. No.: US 2011/0210649 A1
(43) Pub. Date: Sep. 1, 2011

(54) CRYSTAL RESONATOR FOR SURFACE MOUNTING

(75) Inventor: TOSHIHIKO SHIMIZU, Saitama (JP)

(73) Assignee: NIHON DEMPA KOGYO CO., LTD., Saitama (JP)

(21) Appl. No.: 13/030,699

(22) Filed: Feb. 18, 2011

(30) Foreign Application Priority Data
Feb. 26, 2010 (JP) 2010-042269

(51) Int. Cl. H01L 41/053

(52) U.S. Cl. 310/344

(57) ABSTRACT

The crystal resonator for surface mounting includes: a single-layer base substrate, including a pair of crystal holding terminals on a major face; a crystal piece, including an excitation electrode on two major faces, and electrically and mechanically connected to the crystal holding terminals; and a concave metal cover, including an opening end face bonded to an outer peripheral surface of the base substrate through curing of a liquid resin. The end face electrode is electrically connected through an electrically conducting path of the outer peripheral surface extended from the crystal holding terminals, and the crystal resonator for surface mounting is disposed as a structure that includes an end face region of two positions at least being opposite to the electrically conducting path in the opening end face of the metal cover spaced from a front end of a protruding portion through the protruding portion disposed on the opening end face.

### CROSS-REFERENCE TO RELATED APPLICATION

This application claims the priority benefit of Japan patent application serial no. 2010-042269, filed on Feb. 26, 2010. The entirety of the above-mentioned patent application is hereby incorporated by reference herein and made a part of the specification.

### BACKGROUND OF THE INVENTION

1. Field of the Invention

The present invention generally relates to the field of a crystal resonator for surface mounting (hereafter referred to as a surface mount resonator), in particular, to a surface mount resonator, wherein the surface mount resonator is absolutely sealed with a resin to promote a low price.

2. Description of Related Art

### Background of the Invention

A surface mount resonator has a small size and a light weight, such that the surface mount resonator is particularly built in a portable electronic device as a reference source of frequency or time. In recent years, a cheap consumable surface mount resonator with a relatively loose frequency deviation Δf/f, for example, ±150 ppm-250 ppm is proposed. One of the surface mount resonators is provided, in which a crystal piece is carried on a flat base substrate, and a metal cover is covered on the crystal piece, such that the crystal piece is sealed.

### An Example of the Prior Art, Patent Document 1

FIG. 5 includes views of a surface mount resonator according to an example of the prior art, in which FIG. 5(a) is an exploded outside view, FIG. 5(b) is a cross-sectional view of FIG. 5(c) along A-A, and FIG. 5(c) is a plane view without a cover.

In the surface mount resonator, a crystal piece 2 is carried on a base substrate 1 being rectangular when being observed on the plane, and a concave metal cover 3 is covered on the crystal piece 2, such that the crystal piece 2 is sealed. The base substrate 1 is formed by a single-layer of alumina (Al₂O₃) ceramic, and includes a pair of crystal holding terminals 4 on, for example, two end sides of an inner bottom face. An electrically conducting path 5 is extended from the crystal holding terminals 4 to a group of opposite angle portions, and is electrically connected to a mounting terminal 7 on an outer bottom face through an end face electrode 6 of an outer side face. The other group of opposite angle portions on the outer bottom face includes a dummy mounting terminal 7, such that totally 4 terminals exist.

For the above members, firstly, a ceramic green sheet (green sheet before being calcined) being equivalent to the base substrate 1 and including vertical and horizontal rectangular regions is formed. Then, through holes are pre-disposed in cross point regions adjacent to four angle portions of each rectangular region, and calcination is performed under a temperature from 1500° C. to 1600° C. Next, circuit patterns of the crystal holding terminals 4, the electrically conducting path 5, and the mounting terminals 7 are formed on the calcined ceramic sheet by printing with, for example, AgPd alloy. Under the situation, a paste of the AgPd alloy during the printing is coated on inner surfaces of the through holes located in the direction of a group of opposite angles (the so-called through hole processing). Afterwards, the printed circuit patterns and the ceramic sheet are calcined together under a temperature above a melting point (approximately 850° C.) of AgPd.

Further, when the calcined ceramic sheet is vertically and horizontally divided to obtain each base substrate, the through holes are also divided into four parts, so as to form the end face electrode 6. Also, the crystal holding terminals 4 are formed by multiple coatings, thereby, for example, having a thickness (for example, approximately 50 μm) greater than that of the electrically conducting path 5 (for example, 10 μm), such that a major face of the crystal piece 2 is spaced from a surface of the base substrate 1.

The crystal piece 2 includes an excitation electrode 8a as, for example, an AT cutting crystal piece on two major face, and an extraction electrode 8b is extended to two end portions. The extraction electrode 8b is extended from the excitation electrode 8a in a straight line to a center of the two end portions located on opposite directions, and is formed on the entire region along each edge of the two end portions. The extraction electrode 8b along each edge of the two end portions is, for example, formed by being folded back towards opposite sides. Further, the group of opposite angle portions of the crystal piece 2 is fixed to the crystal holding terminal 4 through an electrically conducting bonding agent 9, so as to be electrically and mechanically connected to the crystal holding terminal 4.

In the example, the metal cover 3 includes a flange 3a at an opening end face, and the metal cover 3 is formed by, for example, stainless steel. Further, the metal cover 3 is usually constituted with a kovar alloy having an expansion coefficient being close to the base substrate (alumina ceramic). However, the resin sealing is performed herein, such that even the stainless steel with the different expansion coefficients is used, the strain resulting from the difference of expansion coefficient may be eliminated by using the resin, thereby preventing special problems.

Here, as shown in Patent Document 2, for example, a heat-curing type liquid resin 10 is coated on the opening end face of the metal cover 3. For example, as shown in FIG. 6, the opening end face (flange 3a) of the metal cover 3 is immersed in the liquid resin 10 (FIG. 6(a)), and when the opening end face (flange 3a) of the metal cover 3 is lifted, the liquid resin 10 is transfer-printed (FIG. 6(b)). A thickness of the liquid resin 10 is set to be 10 μm to 20 μm which is greater than the thickness of the electrically conducting path 5. Further, a number 11 in the drawing is a container. Next, the opening-end face of the metal cover 3 leans against an outer periphery of each rectangular region of the base substrate 1 wafer carrying the crystal piece 2. Then, the liquid resin 10 is heated, and the metal cover 3 is bonded to each rectangular region for being sealed.

Thus, a plurality of surface mount resonators with the sealed crystal piece 2 carried on the rectangular region (equivalent to the base substrate) of the ceramic sheet is obtained. Further, each surface mount resonator is obtained through division. Then, the metal cover 3 may also be sealed in the respectively pre-divided base substrate 1, so as to form the surface mount resonator.

### Prior Art Documents

### Patent Document

[Patent document 1] Japanese Patent Application No. 2009-257910

[Patent Document 2] Japanese Patent Publication No. 3183065

[Patent Document 3] Japanese Patent Publication No. 3489508

### Problems in the Prior Art

However, in the surface mount resonator with the above structure, the metal cover 3 is sealed in the base substrate 1 by using the liquid resin 10, such that the metal cover 3 contacts with the electrically conducting path 5 extended to the group of opposite angle portions of the base substrate 1, thereby generating an electrical short circuit. That is to say, as described above, the circuit pattern including the electrically conducting path 5 is formed through the printing of the AgPd alloy, such that the thickness of the circuit pattern approximately achieves 10 μm, and is protruded from the surface of the base substrate 1 (ceramic green sheet).

Therefore, when the opening end face of the metal cover 3 coated with the liquid resin 10 is positioned on the outer peripheral surface of the base substrate 1, the group of the opposite angle portions of the metal cover 3 coated with the liquid resin 10 leans against the electrically conducting path 5 extended to the opposite angle portion of the base substrate 1 and being protruded. Further, due to the weight of the metal cover 3, the liquid resin 10 attached to the electrically conducting path 5 is pushed aside. Therefore, the liquid resin 10 on the electrically conducting path 5 becomes thin, the group of opposite angle portions of the metal cover 3 may contact with the electrically conducting path 5, so as to generate the electrical short circuit and result in air leakage. Particularly, the lower the adhesiveness of the liquid resin 10 is, the stronger the above tendency is.

Therefore, for example, it may be considered to increase a coating amount of the liquid resin 10 to increase the thickness or improve the adhesiveness. However, under the situation, when the liquid resin 10 is heated to be cured, due to the thickness or the adhesiveness of the liquid resin 10, the metal cover 3 may generate the position deviation. Further, as shown in Patent Document 3, for example, one may consider to pre-adhere an insulation film (not shown in figure) to the opening-end face of the metal cover 3; however, under the situation when a step of adhering the insulation film is added, productivity is reduced, and a low cost is precluded.

### SUMMARY OF THE INVENTION

### Objective of the Invention

Accordingly, the present invention is directed to a surface mount resonator, capable of preventing an electrical short circuit and being absolutely sealed, such that productivity is maintained and cost is low.

The present invention provides a crystal resonator for surface mounting. In one embodiment of the invention, the crystal resonator for surface mounting includes: a single-layer base substrate, including a pair of crystal holding terminals on a major face, and electrically connected to a mounting terminal on the other major face through an end face electrode on an outer side face; a crystal piece, including an excitation electrode on two major faces, and electrically and mechanically connected to the crystal holding terminals; and a concave metal cover, including an opening end face bonded to an outer peripheral surface of the base substrate through curing of a liquid resin, in which the end face electrode is electrically connected through an electrically conducting path of the outer peripheral surface extended from the crystal holding terminals, and the crystal resonator for surface mounting is disposed as a structure that includes an end face region of two positions at least being opposite to the electrically conducting path in the opening-end face of the metal cover spaced from a front end of a protruding portion through the protruding portion disposed on the opening-end face.

### Effect of the Invention

According to the above structure, the end face region of the metal cover being opposite to the electrically conducting path of the outer peripheral surface connected to the end face electrode is spaced from the front end of the protruding portion. When the opening-end face of the metal cover is positioned on the outer peripheral surface of the base substrate, as the end face region being opposite to the electrically conducting path is spaced from the front end of the protruding portion, similarly, the end face region is spaced from the outer peripheral surface of the base substrate.

Therefore, for example, if the liquid resin is pre-coated on the opening-end face of the metal cover for performing positioning, the liquid resin on the end face region being opposite to the electrically conducting path does not bear the weight of the cover, such that the liquid resin surely remains between the electrically conducting path and the end face region. Therefore, the end face region of the metal cover is spaced from the electrically conducting path to maintain the electrical insulation, and the part is surely sealed.

In addition, in the present invention, the objective is implemented through the construction of the metal cover, such that other manufacturing steps need not to be altered, so as maintain productivity and promote a low cost.

In one embodiment of the invention, the metal cover includes a flange at the opening-end face, and the protruding portion is formed on the flange. Thus, the structure of the metal cover and a position for forming the protruding portion become definitive, and a sealing path maintaining a bonding strength and an air tightness of the resin is ensured through the flange.

In one embodiment of the invention, the flange of the metal cover is staggered up and down such that the protruding portion is formed with a step-difference construction where an upper step surface is parallel with a lower step surface. Thus, the structure of the protruding portion becomes more specific, and for example, only a mould shaping the metal cover is altered to achieve the objective.

In one embodiment of the invention, a groove is disposed from an upper surface towards a lower surface of the flange of the metal cover, such that the groove is protruded to the lower surface side to form the protruding portion. Thus, after the metal cover including the flange is formed instead of altering the mould, the groove is protruded through pressing, thereby further promoting the low cost.

In one embodiment of the invention, the electrically conducting path from the crystal holding terminals is extended to a group of opposite angle portions of the base substrate, and the end face region of the two positions spaced from the protruding portion is disposed as four angle portions including the other group of opposite angle portions of the base substrate. Thus, when the metal cover is bonded to the base substrate, directivity of the metal cover is not considered, such that operation is enhanced. Afterwards, the surface of the metal cover displays sources or functions, etc.

In order to make the aforementioned and other objectives, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a front view of a surface mount resonator according to a first embodiment of the present invention.

FIGS. 2(a), 2(b), 2(c) include views of a metal cover according to a first embodiment of the present invention, in which FIG. 2(a) is a front view, FIG. 2(b) is a side view, and FIG. 2(c) is a partial enlarged cross-sectional view.

FIGS. 3(a), 3(b) include views of a second embodiment of the present invention, in which FIG. 3(a) is a front view of a surface mount resonator, and FIG. 3(b) is a plane view of a metal cover.

FIGS. 4(a), 4(b) include views of another embodiment of the present invention, in which FIG. 4(a) is a view of a metal cover, and FIG. 4(b) is a plane view of the metal cover.

FIGS. 5(a), 5(b), 5(c) include views of a surface mount resonator according to an example of the prior art, in which FIG. 5(a) is an exploded outside view, FIG. 5(b) is a cross-sectional view of FIG. 5(c) along A-A, and FIG. 5(c) is a plane view without a cover.

FIGS. 6(a), 6(b) include partial cross-sectional views according to an example of the prior art, in which a liquid resin is attached to a metal cover, in which FIG. 6(a) shows an immersed state, and FIG. 6(b) shows a lifted state.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

### First Embodiment

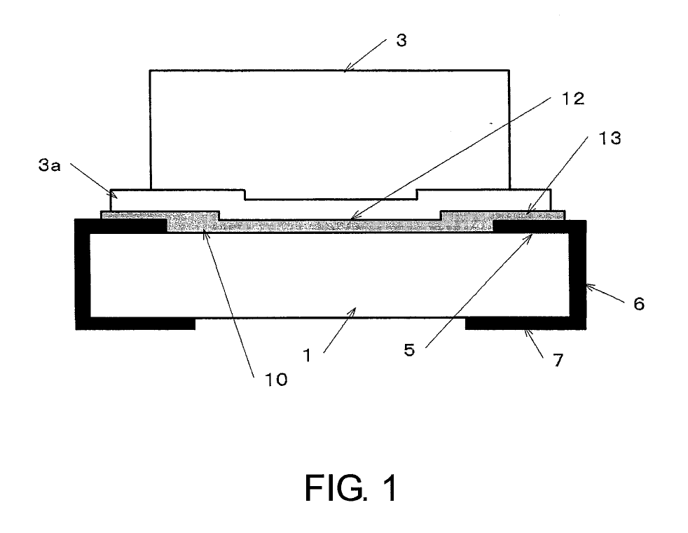

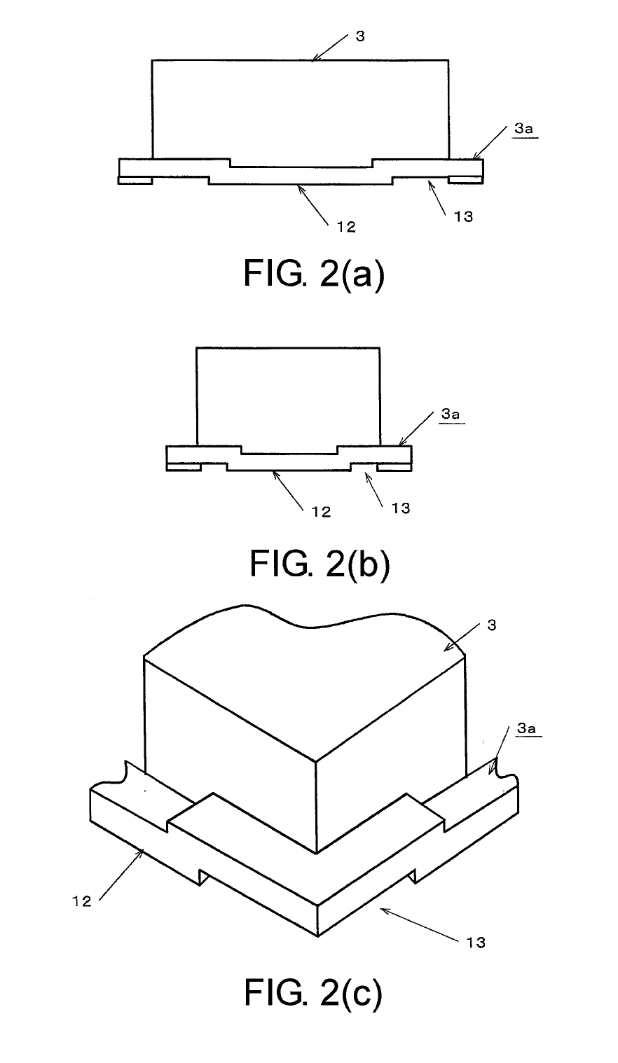

In the following, the first embodiment of the present invention is illustrated according to FIG. 1 (a front view) and FIGS. 2(a), 2(b), 2(c) (a front view, a side view, and a partial enlarged view of a metal cover). Further, the parts being the same as that of the prior art have the same numbers, and the illustration thereof is simplified or the explanation thereof is omitted. Also, in the drawings, for convenience, an angle portion is disposed as a straight line, but it is actually a circular arc.

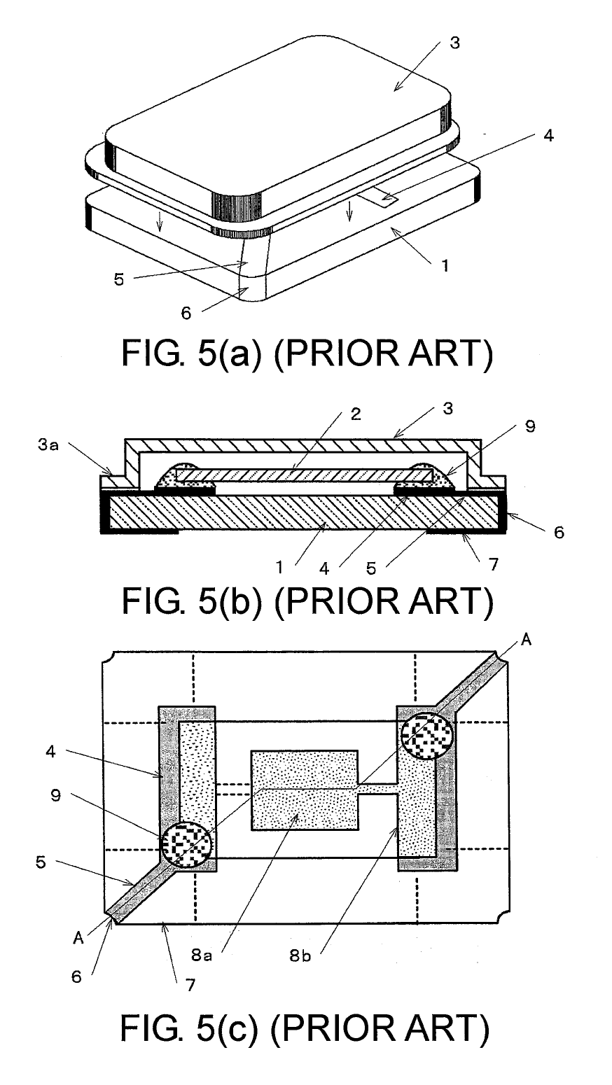

As described above (referring to FIGS. 5(a), 5(b), 5(c)), in a surface mount resonator, two end portions of a crystal piece 2 to which an extraction electrode 8b is extended from an excitation electrode 8a are fixed to crystal holding terminals 4 of a base substrate 1 formed by a single-layer of ceramic through an electrically conducting bonding agent 9. A flange 3a used as an opening end face of a metal cover 3 is bonded to an outer peripheral surface of the base substrate 1 by using a liquid resin 10, so as to seal the outer peripheral surface of the base substrate 1, such that the crystal piece 2 is sealed. Further, the flange 3a is formed to ensure a sealing path during the resin sealing.

The crystal holding terminal 4 is electrically connected to a mounting terminal 7 of a group of opposite angle portions on an outer bottom face through an electrically conducting path 5 and an end face electrode 6, and the other group of opposite angle portions includes a dummy mounting terminal 7. The above circuit pattern is formed through printing of an AgPd alloy with a thickness of approximately 10 μm. However, in order to prevent the base substrate 1 from contacting with the crystal piece 2, the crystal holding terminal 4 is formed by multiple coatings, so as to approximately achieve 50 μm.

Further, in this embodiment, the metal cover 3 includes a protruding portion 12 at a central portion of four edges of the flange 3a used as the opening end face, such that four angle portions of the flange 3a are spaced from a front end of the protruding portion 12. Further, for convenience, the spaced four angle portions are disposed as gap portions 13 of the opening end face (flange 3a). Under the situation, a thickness of the metal cover 3 (plate material) is set as 70 μm, and a distance spaced from the front end of the protruding portion 12 is approximately set as 10 μm-20 μm. The spaced distance (10 μm-20 μm) is set to be smaller than a thickness (70 μm) of the metal cover 3, and is set to be greater than a thickness (10 μm) of the electrically conducting path 5.

In this embodiment, a parallel step-difference construction is adopted, that is, the central portion of the four edges of the flange 3a and the flange 3a of the four angle portions are staggered up and down, the central portion is disposed as a low step surface, and the four angle portions are disposed as an upper step surface. Thus, the four angle portions of the flange 3a are disposed as the gap portions 13. A mould shaping the metal cover 3 is altered, so as to obtain the gap portions 13.

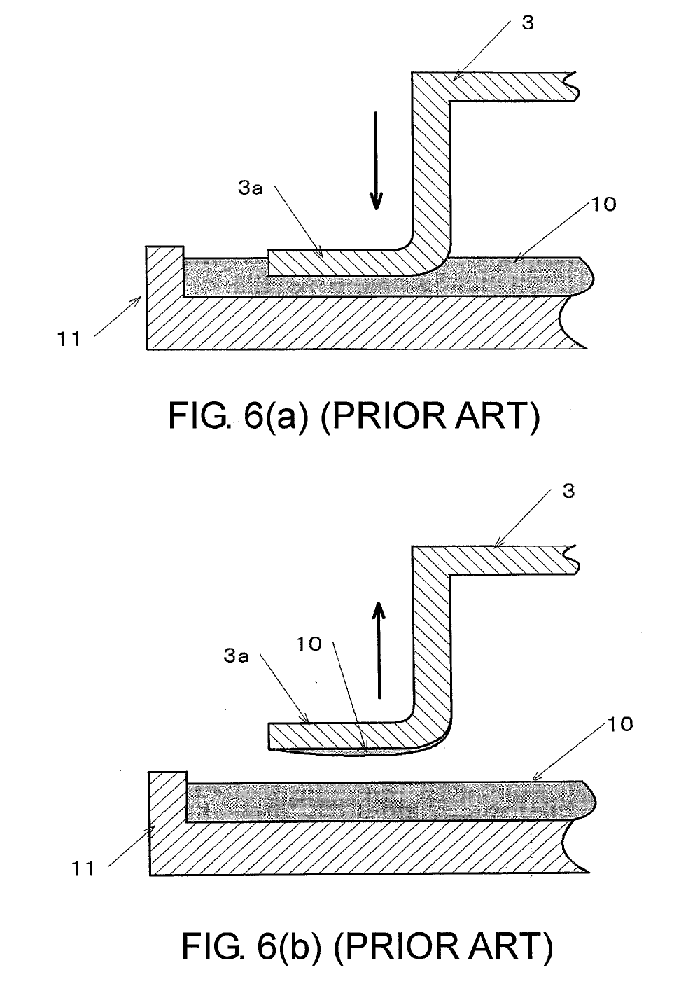

Further, similar to the above (referring to FIG. 6), firstly, the liquid resin 10 is transfer-printed to the opening end face of the metal cover 3, that is, the lower surface of the central portion and the flange 3a of the four angle portions. Under the situation, for example, the thickness of the flange 3a is partially immersed in the liquid resin 10, and the liquid resin 10 fills the gap portion 13 of the opening end face. Next, the opening end face of the metal cover 3 is positioned to an outer peripheral surface of a rectangular region (equivalent to the base substrate 1) of the base substrate 1 wafer, such that the opening end face of the metal cover 3 leans against the outer peripheral surface. Next, the liquid resin 10 is heated to be cured, the opening end face of the metal cover 3 is bonded to the outer peripheral surface of the base substrate 1, and the crystal piece 2 is sealed. Finally, the base substrate 1 wafer is divided into each base substrate 1 to obtain a plurality of surface mount resonators.

According to the above-mentioned structure, through the protruding portion 12 disposed on the central portion of each edge of the flange 3a, the four angle portions of the flange 3a are spaced from the outer peripheral surface of the base substrate 1. Therefore, when the opening end face (the lower surface of the flange 3a) of the metal cover 3 is positioned on the outer peripheral surface of the base substrate 1, the lower surface of the four angle portions of the flange 3a is spaced from the outer peripheral surface of the base substrate 1. Further, here, the spaced distance between the gap portions 13 of the four angle portions of the flange 3a and the front end of the protruding portion 12 (the spaced distance between the gap portions 13 and the base substrate 1) is set to be 10 μm-20 μm being greater than the thickness (10 μm) of the electrically conducting path 5 of the group of opposite angle portions.

Therefore, even the liquid resin 10 is transfer-printed to (coated on) the lower surface of the flange 3a of the metal cover 3 and the metal cover 3 is positioned on (leans against) the outer peripheral surface, the lower surface of the flange 3a being opposite to the electrically conducting path 5 of the group of opposite angle portions of the base substrate 1 does not contact with the electrically conducting path 5. To sum up, the spaced distance (10 μm-20 μm) of the gap portion 13 is increased to be greater than the thickness (10 μm) of the electrically conducting path 5 calculated from the outer peripheral surface of the base substrate 1, such that the metal cover 3 does not physically contact with the electrically conducting path 5. Thus, an electrical short circuit resulting from the metal cover 3 and the electrically conducting path 5 of the pair of crystal holding terminals 4 may be prevented. Further, the spaced distance is set to be 20 μm being smaller than the thickness (70 μm) of the metal cover 3, such that when the liquid resin 10 is transfer-printed, the liquid resin 10 fills the gap portion 13.

Further, the gap portions 13 herein are disposed on the four angle portions of the metal cover 3, such that the metal cover 3 may be positioned on the base substrate 1 without the consideration of the directivity of the metal cover 3. Therefore, the metal cover 3 is mounted on the base substrate 1, such that the mounting operation becomes easy and the operation is enhanced. However, even if the gap portions 13 are only disposed in the group of opposite angle portions of the metal cover 3, the basic effect is the same, such that the situation is not excluded.

### Second Embodiment

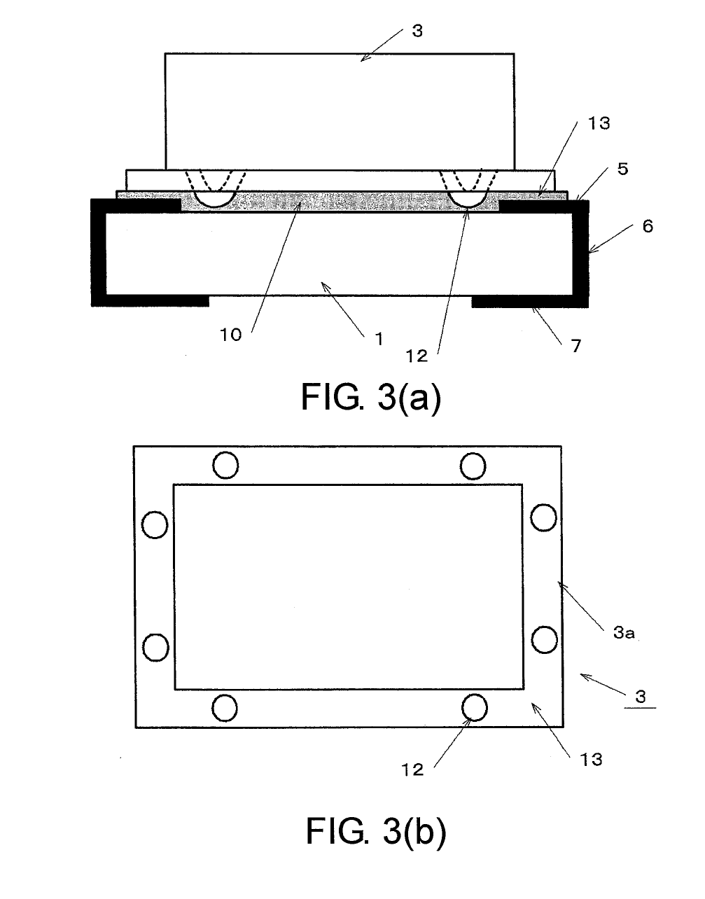

In the second embodiment, as shown in FIGS. 3(a), 3(b) (a front view, and a plane view of the metal cover), the protruding portion 12 disposed on the flange 3a of the metal base is formed through protruding process. That is to say, from the upper surface to the lower surface of the flange 3a on the metal base, grooves are formed in a manner that the front end presses a spherical protrusion, such that the grooves are protruded towards the lower surface side, thereby forming the hemispherical protruding portions 12 (raising portions). For example, the flange 3a is formed on the pre-formed metal cover 3 through the pressing process.

Particularly, every two of the hemispherical protruding portions 12 are respectively disposed at two adjacent edges of the opposite angle portion of the metal cover 3 being opposite to the group of opposite angle portions to which the electrically conducting path 5 is extended from the crystal holding terminal 4. Further, in this embodiment, the two hemispherical protruding portions 12 are also respectively disposed on two edges of the other group of opposite angle portions, and totally eight hemispherical protruding portions 12 are disposed on the two edges of each four angle portions. However, the hemispherical protruding portions 12 are respectively closely disposed on the four angle portions.

Thus, the gap portion 13 is formed on the opposite angle portion of the metal cover 3 by particularly using the hemispherical protruding portions 12 of the group of opposite angle portions, such that the electrical short circuit with the electrically conducting path 5 of the group of opposite angle portions may be prevented. Further, the hemispherical protruding portions 12 are disposed on the two edges of the four angle portions, such that when the metal cover 3 is positioned on the base substrate 1, the stability may be ensured. However, in order to improve the stability, the gap portions 13 are formed on the group of opposite angle portions.

Further, the protruding portions 12 herein are formed by using the protruding process, such that a new mould of the metal cover 3 is not required, thereby further improving the productivity and promoting a lower cost.

### Other Matters

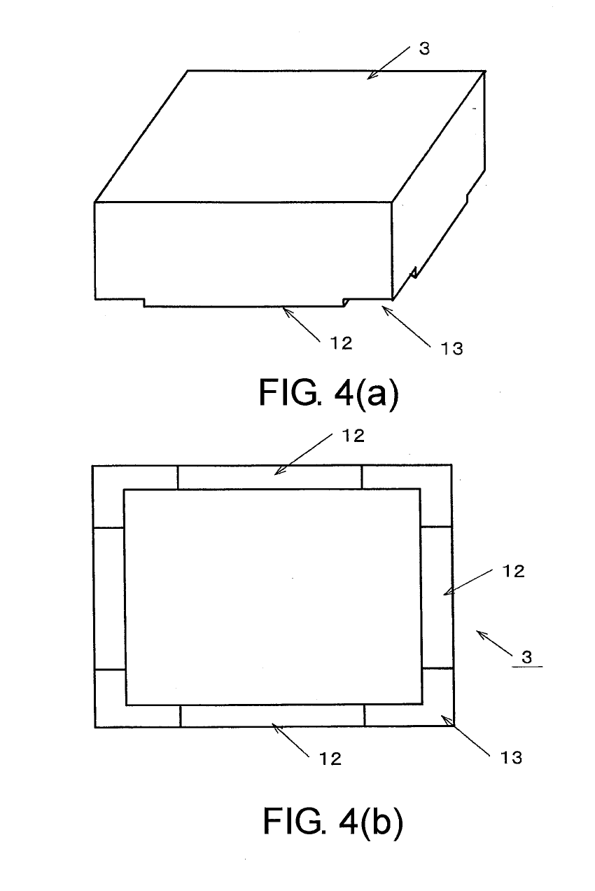

In the above embodiments, the metal cover 3 includes the flange 3a, but for example, even when the miniaturization is performed as shown in FIGS. 4(a), (b) and the flange 3a is omitted, and the thickness of the opening end face is just the thickness of the metal cover 3, it is also applicable. That is to say, the protruding portion 12 is disposed on the central portion of each edge of the opening end face, and the gap portions 13 enabling the four angle portions to be spaced are disposed.

Further, the electrically conducting path 5 from the crystal holding terminal 4 is extended to the group of opposite angle portions, but it should be understood that the disposition of the electrically conducting path 5 is limited as such. For example, the electrically conducting path 5 may be extended to the central portion of the two end sides. Further, the electrically conducting path 5 may be connected to the mounting terminal 7 of the two end sides on the outer bottom face through the end face electrode 6 of the same position. Under the situation, the mounting terminal 7 is a dual terminal. Further, although the extraction electrode 8b is extended to the two end portions of the crystal piece 2, even it is also applicable that the extraction electrode 8b is extended to two sides of one end portion and the part is fixed.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A crystal resonator for surface mounting, comprising:
a single-layer base substrate, comprising a pair of crystal holding terminals on a major face, and electrically connected to a mounting terminal on an other major face through an end face electrode on an outer side face;
a crystal piece, comprising an excitation electrode on two major faces, and electrically and mechanically connected to the crystal holding terminals; and
a concave metal cover, comprising an opening-end face bonded to an outer peripheral surface of the single-layer base substrate through hardening of a liquid resin,
wherein the end face electrode is electrically connected through an electrically conducting path of the outer peripheral surface extended from the crystal holding terminals, and
an end face region of two positions at least being opposite to the electrically conducting path in the opening-end face of the metal cover is spaced from a front end of a protruding portion through the protruding portion disposed on the opening-end face.

2. The crystal resonator for surface mounting according to claim 1, wherein the metal cover comprises a flange at the opening-end face, and the protruding portion is formed on the flange.

3. The crystal resonator for surface mounting according to claim 2, wherein the flange of the metal cover is staggered up and down such that the protruding portion is formed with a step-difference construction where an upper step surface is parallel with a lower step surface.

4. The crystal resonator for surface mounting according to claim 2, wherein a groove is disposed from an upper surface towards a lower surface of the flange of the metal cover, such that the groove is protruded to the lower surface side to form the protruding portion.

5. The crystal resonator for surface mounting according to claim 1, wherein the electrically conducting path from the crystal holding terminals is extended to a group of opposite angle portions of the single-layer base substrate, and the end face region of the two positions spaced from the protruding portion is disposed as four angle portions comprising an other group of the opposite angle portions of the single-layer base substrate.
